(19) United States
(12) Patent Application Publication
(10) Pub. No.: US 2009/0045494 A1
(43) Pub. Date: Feb. 19, 2009

(54) METHOD FOR MANUFACTURING A MICROELECTRONIC PACKAGE

(75) Inventors: Geert Langereis, Eindhoven (NL); Ivar J. Boerefijn, Veldhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/282,481

(22) PCT Filed: Mar. 9, 2007
(86) PCT No.: PCT/IB2007/050790

§ 371 Date: Sep. 10, 2008

(30) Foreign Application Priority Data
Mar. 14, 2006 (EP) 06111124.1

(51) Int. Cl. H01L 23/48; H01L 21/50

(52) U.S. Cl. 257/678; 438/106; 257/E23.01; 257/E21.499

(57) ABSTRACT

The invention relates to a method of packaging an electronic microsystem (200) and further to such a packaged device. With the method a packaged electronic microsystem (200) can be manufactured using a flexible foil (80) having conductive tracks (100) on at least on side of the flexible foil. The electronic microsystem (200) and the flexible foil (80) are arranged in a way that a sealed or even hermetic package can be realized and contact pads (210) of the electronic microsystem (200) are connected to conductive tracks (100) extending to the outer surface of the packaged device after folding the flexible foil (80) in the proposed way. No vias or throughholes in the flexible foil (80) are needed.

The present invention relates to a method of manufacturing a microelectronic package comprising an electronic microsystem, the electronic microsystem can be a Micro ElectroMechanical System (MEMS), a Microfluidic device, an integrated circuit (IC) or a combination of at least two of these devices. Furthermore, the present invention relates to a package comprising an electronic microsystem.

Electronic microsystems are commonly provided as individual, prepackaged units. Each electronic microsystem is mounted in a package, which in turn is mounted on a circuit panel, such as a printed circuit board, and the package electrically connects the contacts of the electronic microsystem to conductors on the circuit panel. Often via bonds are used to connect the contacts of electronic microsystem to the conducting traces of the package in electrically conductive way. These via bonds are small wires of e.g. gold extending from one electrical contact point to another electrical contact point mostly through the air introducing unwanted parasitic effects.

Examples of packages without via bonds are known from US 2005/0233496. In one embodiment a stacked microelectronic assembly comprises a flexible sheet having an obverse surface and a reverse surface and including at least a first panel and a second panel. The second panel and the first panel are adjacent to each other, the second panel including terminals on the reverse surface for mounting to an external circuit. The first panel includes a non-overmolded microelectronic element mounted thereon. The microelectronic element having a rear face and a front face surface, wherein the front face surface confronts the obverse surface of the first panel. During manufacture the flexible sheet is folded to create a stacked microelectronic assembly such that the rear face of the first microelectronic assembly confronts and substantially contacts the obverse surface of the second panel. This results in the second panel being kept substantially flat during subsequent mounting to the external circuit. The flexible sheet includes a metallization layer and a layer of dielectric and the dielectric layer includes through-holes or vias. These through-holes or vias are holes etched or stamped in the dielectric layer filled with a conductive material for electrically coupling the contacts of the microelectronic element to the traces of the metallization layer for the purpose of contacting the contacts of the microelectronic element to a circuit panel, such as a printed circuit board (PCB). The need of the through-holes or vias enhances the complexity of the processing of the flexible sheet causing higher costs.

It is an objective of the present invention to provide a package for electronic microsystem being robust, cost effective and easy to manufacture. The objective is achieved by means of a method of manufacturing a microelectronic package comprising an electronic microsystem with electronic contact pads and at least one flexible foil consisting of an isolating layer and at least one conductive layer on at least one side of the isolating layer, comprising the following steps:

sectoring the flexible foil in at least five portions

structuring the at least one conductive layer in a way that there is at least one conductive track

placing the electronic microsystem on one portion of the flexible foil

folding the flexible foil in a way that the flexible foil covers at least parts of at least three sides of the electronic microsystem and at least two portions of the flexible foil are facing each other

contacting at least one contact pad of the electronic microsystem with at least one of the at least one conductive track of the conductive layer of the flexible foil in an electrically conductive way, wherein at least one conductive track contacted with the at least one contact pad extends to a surface of the microelectronic package so that the at least one conductive track extending to a surface of the microelectronic package can be contacted to other conductive structures not comprised by the electronic microsystem and the flexible foil. The flexible foil is preferably in one dimension longer than in the other building a kind of strip. The sectoring in a subsequent segmentation of portions is done perpendicular to the longest side of the flexible foil and adapted to the dimensions of the microsystem. The structuring of the conductive layer can be done by optical patterning of the conductive layer or layers by means of photoresist followed by an etching procedure adapted to the material of the flexible foil and the material of the conductive layer or layers. Further the structuring can be done by means of laser abrasion as described in detail in the European patent application 05108280.8 filed on Sep. 9, 2005 with the title “A method of manufacturing a microsystem, such a microsystem, a stack of foils comprising such a microsystem, an electronic device comprising such a microsystem and use of the electronic device”. The folding procedure is based on the sectoring of the flexible foil. Each portion of the flexible foil is finally one side of the folded flexible foil. Each portion of the folded foil encloses an angle of around 90° with the preceding portion and/or the succeeding portion of the flexible foil. It is always assumed that there is an interconnecting portion of the foil if two portions of the flexible foil are placed on top of each other. This interconnecting portion of the foil between the two portions placed on top of each other encloses an angle of around 90° with the preceding portion and the succeeding portion. The width of this interconnecting portion can be near to zero depending on the thickness of the flexible foils and/or spacers that are placed between the portions of the flexible foils stacked on top of each other in order to release the stress of the flexible foil. In this case the two portions placed on top of each other seem to enclose an angle of around 180°. The flexible foil and the microsystem can be adhered to each other by using adhesives. The adhesive can also be placed on the parts of the foil those are folded on each other. Another possibility is to use material for the isolating layer of the flexible foil that adheres to the microsystem and sticks to itself possibly activated by special physical conditions as e.g. temperature and pressure. Due to the fact that the electrically conductive track extends to the outer surface of the package a direct access from the outside to the conductive track and the contact pads of the microsystem can be established without the need of additional vias or through holes in the flexible foil. Consequently this special kind of packaging enables a simple and cost effective method of contacting the electrical contact pads of the electronic microsystem to electrical contact pads on a printed circuit board or other substrates that are used to assemble and electrically contact different subunits of an electronic system. It simplifies the production of the package reducing the costs and enhancing the reliability of the packaged electrical microsystem. Further, no via bonds are needed to contact different contact pads of the microsystem with each other if one or more conductive tracks on the flexible foil are used instead. A cost effective and reliable connection between different parts of the electronic microsystem can be established.

In one embodiment of the invention the flexible foil has five subsequent portions, a first portion, a second portion, a third portion, a fourth portion and a fifth portion and the at least one conductive track contacted to the contact pads of the electronic microsystem and extending to a surface of the microelectronic package that can be contacted to other conductive structures not comprised by the electronic microsystem and the flexible foil is on the second side of the flexible foil, extending from the fifth portion of the flexible foil at least to the fourth portion of the flexible foil. The electronic microsystem is placed on the first side of the first portion of the flexible foil. The flexible foil is folded in a way that the first portion of the flexible foil covers the side of the electronic microsystem opposite to the side of the microsystem with the contact pads. The second portion of the flexible foil covers one side of the electronic microsystem essentially perpendicular to the side of the microsystem covered by the first portion of the flexible foil. The third portion of the flexible foil is further folded in a way that it builds the top surface of the packaged electronic microsystem separated by means of the fifth portion of the flexible foil from the side of the electronic microsystem with the contact pads. The second side of the fifth portion of the flexible foil folded below the third portion of the flexible foil faces the contact pads of the electronic microsystem enabling the electric contact between the contact pads of the electronic microsystem and at least one conductive track on the second side of the flexible foil. The at least one conductive track electrically contacted to the contact pads of the electronic microsystem extends to the fourth portion of the flexible foil where it is not covered by a portion of the flexible foil or a side of the electronic microsystem. If the size of the fourth portion of the flexible foil isn't sufficient for contacting the conductive track to e.g. a printed circuit board it further extends to the third portion of the flexible foil or even to the second portion or first portion of the flexible foil.

In one embodiment of the invention the flexible foil has five subsequent portions, a first portion, a second portion, a third portion, a fourth portion and a fifth portion and the at least one conductive track contacted to the contact pads of the electronic microsystem and extending to a surface of the microelectronic package that can be contacted to other conductive structures not comprised by the electronic microsystem and the flexible foil is on the first side of the flexible foil, extending at the latest from the third portion of the flexible foil at least to the fourth portion of the flexible foil. The electronic microsystem is placed on the first side of the first portion of the flexible foil. The flexible foil is folded in a way that the first portion of the flexible foil covers the side of the electronic microsystem opposite to the side of the microsystem with the contact pads whereby the limitation to a microsystem with only one side with contact pads is only for clearity of the description. The second portion of the flexible foil covers one side of the electronic microsystem essentially perpendicular to the side of the microsystem covered by the first portion of the flexible foil. The third portion of the flexible foil is further folded in a way that the first side of the third portion of the flexible foil faces the side of the electronic microsystem with the contact pads. The fifth portion and the third portion of the flexible foil essentially enclose angles of around 90° with the fourth portion of the flexible foil, whereby the second surface of the third portion of the flexible foil faces the second surface of the fifth portion of the flexible foil. The at least one conductive track on the first side of the third portion of the flexible foil electrically contacted to the contact pads of the electronic microsystem extends to the fourth portion of the flexible foil where it is not covered by a portion of the flexible foil or a side of the electronic microsystem. If the size of the fourth portion of the flexible foil isn't sufficient for contacting the conductive track to e.g. a printed circuit board it further extends to the fifth portion of the flexible foil. In other configurations of this embodiment the conductive track or tracks can extend from the first side of the first portion of the flexible foil up to the at least fourth portion of the flexible foil in order to electrically contact contact pads on the side of the electronic microsystem facing the first side of the first portion of the flexible foil. In addition further conductive tracks not extending to a surface of the microelectronic package that can be contacted to other conductive structures not comprised by the electronic microsystem and the flexible foil can be structured on the first side of the flexible foil extending from the first portion of the flexible foil to the third portion of the flexible foil in order to contact contact pads on the bottom side of the electronic microsystem facing the first side of the first portion of the flexible foil with contact pads on the top side of the electronic microsystem facing the first side of the third portion of the flexible foil.

In a further embodiment of the invention the flexible foil has at least seven portions with two conductive layers one on each side of the isolating layer of the flexible foil, comprising the additional steps: structuring the second conductive layer of the flexible foil in a way that after placing the electronic microsystem and folding the flexible foil there is at least one overlapping contact area between at least two conductive tracks, with a first conductive track on the first and a second conductive track on the second side of the isolating layer of the flexible foil, contacting the at least two conductive tracks in a electrically conductive way by means of the at least one overlapping contact area. This method can e.g. be used to connect contact pads on one side of the electronic microsystem e.g. the bottom side with further contact pads on another side e.g. the top side of the electronic microsystem and extending the functional contacts of the packaged device to the outside of the package without vias or throughholes in the isolating layer of the flexible foil. Further it's possible to stack more than one electronic microsystem on top of each other with the flexible foil in between and interconnect the different electronic microsystems with each other without vias or throughholes

The electronic microsystem comprises at least one out of the group, MEMS device, Microfluidic device or an IC. Especially if a combination of a MEMS device and an IC or an Microfluidic device and an IC or an combination of all three devices is packaged the conductive tracks on the flexible foil can be used to interconnect the electrical contact pads of the different devices. No additional via bonds are needed reducing parasitic effects on the one hand side and costs on the other hand side. Additionally the reliability is enhanced by the avoidance of sensitive via bonds.

In a further embodiment the electronic microsystem comprises a MEMS device or Microfluidic device consisting of the same kind of flexible foils for the present invention that are used for the microelectronic package. The MEMS device or Microfluidic device consists of structured and stacked foils as described in the European patent application 05108280.8 filed on Sep. 9, 2005 with the title “A method of manufacturing a microsystem, such a microsystem, a stack of foils comprising such a microsystem, an electronic device comprising such a microsystem and use of the electronic device”. In this patent application a multitude of MEMS devices and Microfluidic devices are described that are realized by means of structured and stacked foils. The advantage of using the same kind of foil for the present invention as described in detail in the patent application mentioned above is that the microelectronic device and the package can be done in one process. The flexible foil used for the package is stacked together with the structured foils used for the microelectronic device. In an additional process step the foil for the package is folded in the same way as described above and the electrically conductive connection between the conductive tracks on the foil used for the package and the MEMS or Microfluidic device is established. One option to establish the electrically conductive connection is the use of structured electrically conductive adhesives. Further, adhesive layers can be used to glue the MEMS or Microfluidic device with the foil used for the package in order to seal the package. The mechanical stress of the foil used for the package can be reduced by spacers formed by means of stack of foils placed on the foil used for the package. If an IC is needed for reading or driving signals for the MEMS or Microfluidic device it can be integrated together with the MEMS device or Microfluidic device in a recess formed in the multilayer foil structure. The foil used for the package with the structured electrically conductive layer can then provide the electrical conductive interconnection between the MEMS device or Microfluidic device and the IC.

If the MEMS device, the Microfluidic device, the IC or the combination of IC with the MEMS device or Microfluidic device consists of a compatible material heat and pressure can be used in order to establish a permanent and conducting contact (in the case where conducting traces are placed above each other) between the flexible foil and the MEMS device, the Microfluidic device, the IC or the combination of IC with the MEMS device or Microfluidic device. Especially if the same kind of flexible foil for packaging and the assembly of the structure are used as described above the packaging process can be done in a low cost integrated process. In this embodiment the flexible foil or more precise the isolating layer of the flexible foil adheres as well to another isolating layer of another flexible foil as to the structured electrically conductive layer of another flexible foil in a tight way if heat and pressure is exerted. The temperature that has to be reached by exerting heat depends on the material used for the flexible foil and especially the material of the isolating layer of the flexible foil. In addition the temperature has to be adapted to materials (e.g. solder materials) that are used for electrically connecting the contact pads of the microelectronic device with the electrically conductive tracks of the structured conductive layer of the flexible foil used for packaging. A maximum temperature is given by the melting point of the flexible foil. The pressure is applied perpendicular to the planes of the flexible foils. The pressure is chosen in dependence on the material used for the flexible foil and especially the material of the isolating layer of the flexible foil that high that a reliable permanent contact can be established. More details with respect to the heat and the pressure that is needed are given in the patent application cited above.

The method described in the preceding paragraph can in particular be used to produce sealed or hermetic packages by structuring the at least one conductive layer of the flexible foil in a way that on at least one surface of the microsystem being in contact with the flexible foil at least one area is build that can be joined with the structured flexible foil in a gas-tight way and the at least one area is arranged as a sealing ring around all other areas on the at least one surface of the microsystem being in contact with the flexible foil where the flexible foil with at least one structured conductive layer and the microsystem are joined in a non gas-tight way. The direct contact between the isolating layer of one flexible foil and the isolating layer of another flexible foil or the direct contact between the isolating layer of one flexible and the structured conductive layer of another flexible foil results in a tight contact between two flexible foils. Using this feature a sealing ring around other areas where e.g. two conductive layers faces each other (being sufficient for a electrically conductive contact but being not gas-tight) preventing the contact with moisture in order to improve the reliability of the packaged device or enable even vacuum or protective gas around e.g. the moveable parts of a MEMS device. The same principle can be used if the surface of the electronic microsystem not necessarily a flexible foil itself does have the same properties as the flexible foil with respect to the adherence to the flexible foil as the flexible foil itself.

Preferably, the method according to the present invention is characterized in that the material of the conductive layer comprises a metal from the group consisting of aluminum, platinum, silver, gold, copper and indium tin oxide. The selection of a material from this group is partially determined by requirements as conductivity and/or reliability aspects (corrosion).

Preferably, the method according to the present invention is characterized in that the material for isolating layer of the flexible foil comprises a substance from the group consisting of polyphenyl sulphide (PPS) and polyethylene terephthalate (PET).

Preferably, the method according to the present invention is characterized in that the foil has a thickness between 1 μm and 100 μm. Whereby foils of around 20 μm to 100 μm do offer more reliability if the flexible foil is used for packaging monolythic electronic Microsystems, that means the electronic microsystem is assembled in a different process as the packaging. If the MEMS device consists of patterned and stacked foils as described above, flexible foils with a thickness between 1 μm and 5 μm are preferred because the thickness of the flexible foil determines the available resolution perpendicular to the planes build by the flexible foils for structures building MEMS or Microfluidic devices.

The present invention also relates to a microelectronic package comprising an electronic microsystem with electronic contact pads and at least one flexible foil consisting of an isolating layer and at least one conductive layer on at least one side of the isolating layer, wherein

the flexible foil has at least five portions

the conductive layer comprises at least one conductive track

the folded flexible foil covers at least parts of three sides of the electronic microsystem and at least two portions of the flexible foil are facing each other

at least one contact pad of the electronic microsystem is contacted with at least one of the at least one conductive track of the conductive layer of the flexible foil in an electrically conductive way, wherein the at least one conductive track contacted with the at least one contact pad extends to a surface of the microelectronic package so that the at least one conductive track extending to a surface of the microelectronic package can be contacted to other conductive structures not comprised by the electronic microsystem and the flexible foil.

The present invention will now be explained in greater detail with reference to the figures, in which similar parts are indicated by the same reference signs, and in which:

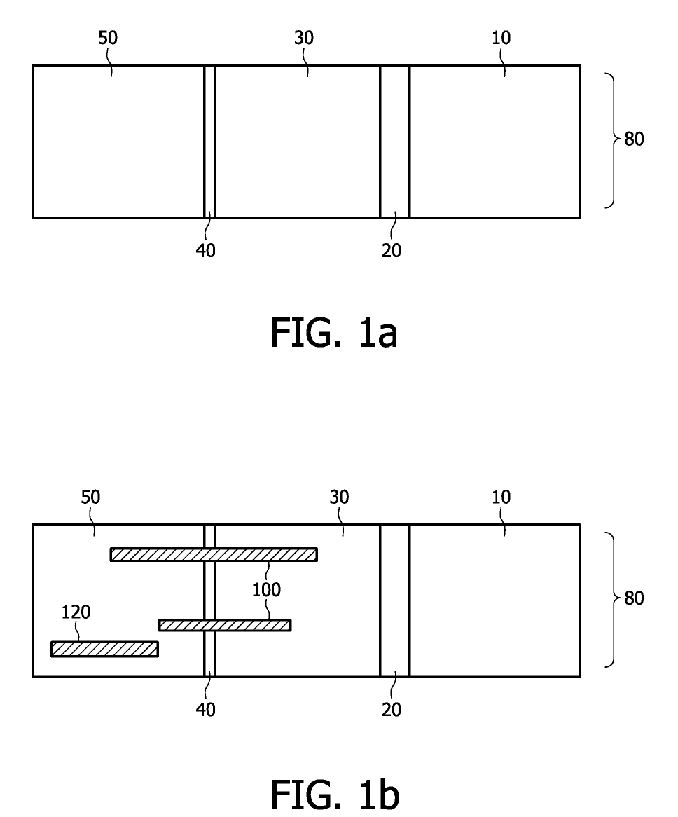

FIGS. 1a and 1b show the first and the second side of a flexible foil with five different portions

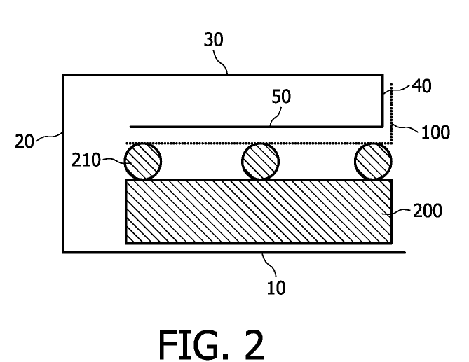

FIG. 2 shows the cross section of one embodiment of a packaged microsystem

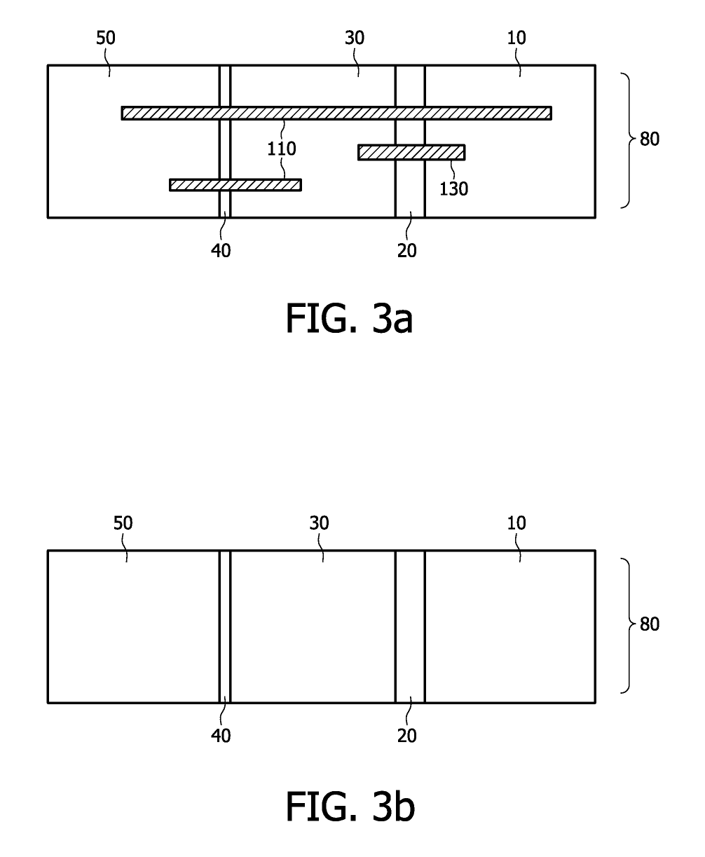

FIGS. 3a and 3b show the first and the second side of another flexible foil with five different portions

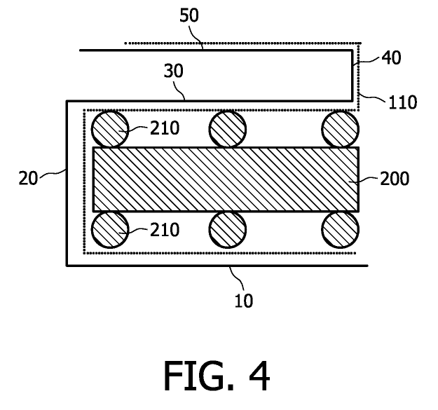

FIG. 4 shows a cross section of a second embodiment of a packaged microsystem

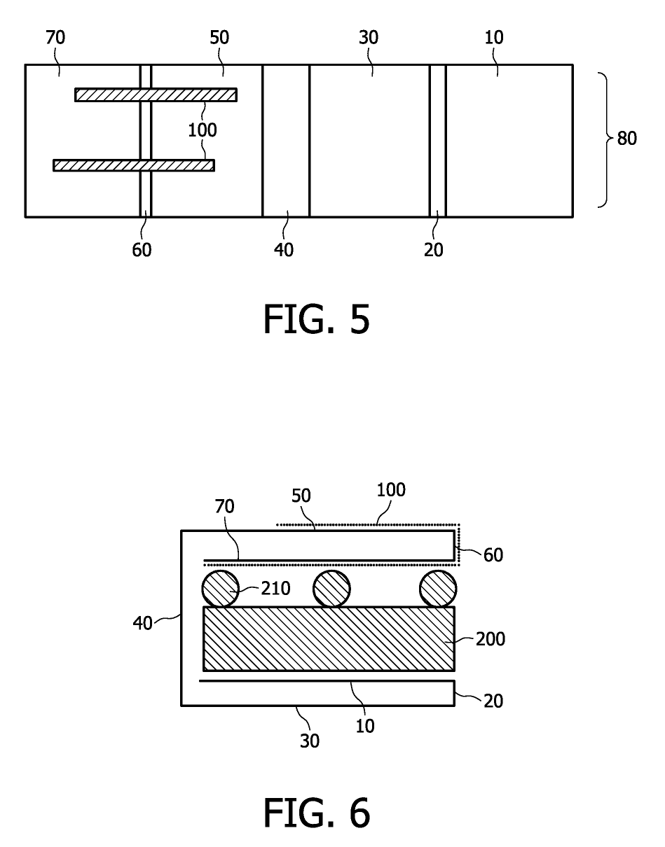

FIG. 5 shows the second side of a flexible foil with seven portions and conductive tracks.

FIG. 6 shows the cross section of a third embodiment of a packaged microsystem

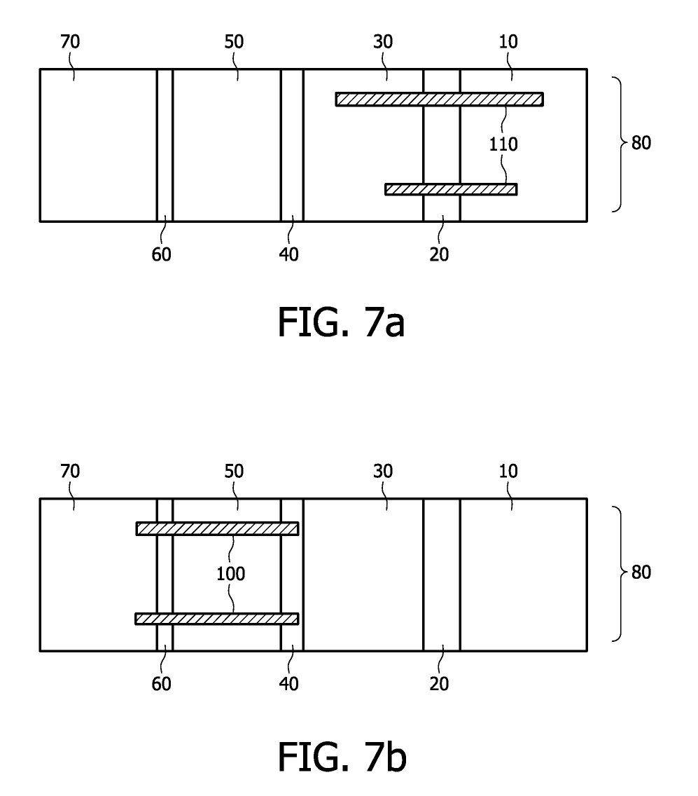

FIGS. 7a and 7b show the first and the second side of another flexible foil with seven different portions

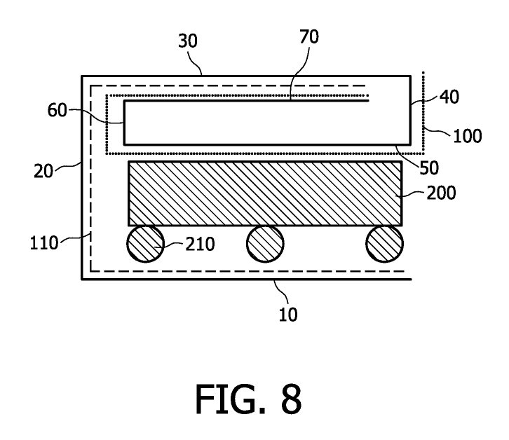

FIG. 8 shows the cross section of a fourth embodiment of a packaged microsystem

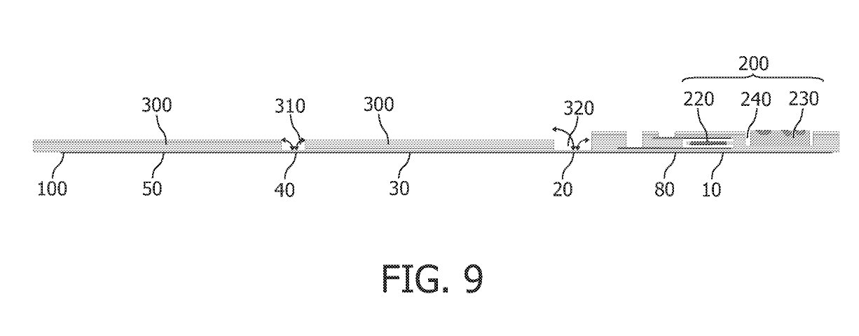

FIG. 9 shows an embodiment of the current invention before folding with a microsystem made of flexible foils

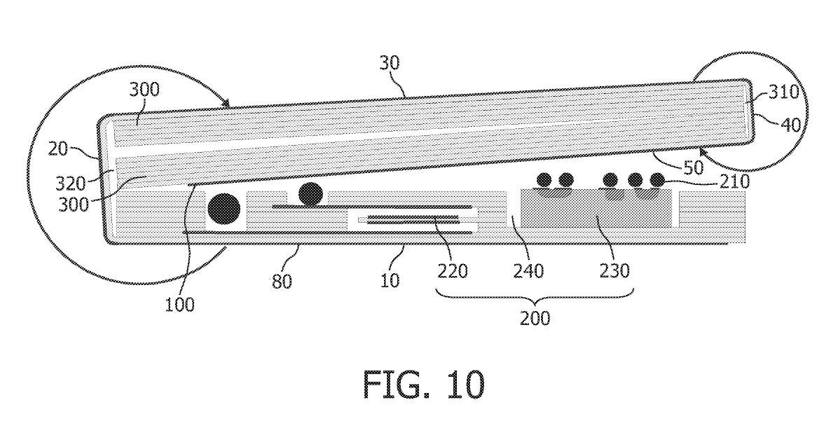

FIG. 10 shows a part of the packaging procedure of a microsystem made of flexible foils

FIGS. 1a and 1b illustrate two sides of a flexible foil 80 having five portions 10, 20, 30, 40 and 50 used for packaging an electronic microsystem. Side one of the flexible foil 80 shown in FIG. 1a has in this embodiment no conducting layer or patterned conductive tracks but this only for clarity and is no principal limitation. Side two as shown in FIG. 1b has conductive tracks 100 and 120 made of e.g. a patterned copper layer. The conductive tracks 100 extend from portion 30 of the flexible foil 80 to portion 50. The conductive track 100 is solely placed on portion 30 of the flexible foil 80.

FIG. 2 shows a side view of an electronic microsystem 200 packaged with a flexible foil 80 with five portions as sketched in FIGS. 1a and 1b. The electronic microsystem is placed on side one of the first portion 10 of the flexible foil 80. The flexible foil 80 is than folded in a way that the second portion 20 covers at least parts of a side of the electronic microsystem 200 not placed on the first portion 10 of the flexible foil 80. Further the flexible foil 80 is folded in a way that the conductive track or tracks 100 on the second side of the flexible foil 80 as sketched in FIG. 1b can be contacted to the electronic contact pads 210 of the electronic microsystem 80 and the first side of the fifth portion 50 of the flexible foil 80 is placed on and in contact with the first side of the third portion 30 of the flexible foil 80. The length of the fourth portion 40 of the flexible foil 80 defined as the dimension which can be seen in FIG. 2 depends on the thickness of the flexible foil 80 or one or two spacers (not shown) placed on the first side of the third portion 30 or the first side of the fifth portion 50 or on the first side of the third portion 30 and the fifth portion 50 of the flexible foil 80. The spacer or spacers may be one or two rectangular blocks of a certain thickness made of e.g. plastic material. A special kind of spacer 300 is discussed in combination with FIG. 9 and FIG. 10. The conductive track or tracks 100 on side two of the flexible foil 80 extend from the fifth portion 50 of the flexible foil 80 to the fourth portion 40 of the flexible foil 80 but it or they can also extend to the third portion 30 as shown in FIG. 1b or even further in order to enable the conductive connection with external contact pacts placed e.g. on a printed circuit board. One or more conductive tracks 120 for the purpose of simplicity not shown in the side view given by FIG. 2 can be used to interconnect different contact pads 210 of the electronic microsystem 200. This can be used if the electronic microsystem 200 consists of different components as a MEMS device and an IC where interconnections are needed in order to get the wanted functionality. In this case conductive track or tracks 120 are a superior alternative to bond wires because they are easy to manufacture and less sensitive. The contact between the conductive pads 210 and the conductive track or tracks 100, 120 can be realized by e.g. soldering where solder balls are e.g. placed on the contact pads of the electronic microsystem 200 or conductive adhesives and the like. A reliable contact between the electronic microsystem 200 and the flexible foil 80 and the parts of the flexible foil placed on each other can be realized by means of an adhesive layer or if the surface of the electronic microsystem 200 being in contact with the flexible foil 80 and the isolating layer of the flexible foil 80 consist of materials those can be glued to each other by means of pressure and heat. An implementation of this kind of embodiment is discussed in combination with FIG. 9 and FIG. 10.

Another embodiment of the invention is shown in FIG. 3a, FIG. 3b and FIG. 4. FIG. 3a shows side one of the flexible foil 80 with five portions 10, 20, 30, 40 and 50. There are conductive tracks 110 extending from the first portion 10 to the fifth portion 50 of the flexible foil 80 and from the third portion 30 to the fifth portion 50 of the flexible foil 80. A further conductive track 130 extends form the first portion 10 to the third portion 30 of the flexible foil 80. Side two of the flexible foil 80 as shown in FIG. 3b doesn't have any conductive tracks. As shown in FIG. 4 the electronic microsystem 200 has in this embodiment contact pads 210 on the bottom side and the top side. The electronic microsystem 200 is placed on the first portion 10 on side one of the flexible foil 80. The flexible foil 80 is than folded in a way that portion 20 covers at least parts of a side of the electronic microsystem 200 not placed on the first portion 10 of the flexible foil 80. Further the flexible foil 80 is folded in a way that side one of the third portion 30 of the flexible foil is near to the electronic microsystem 200 and side two of the fifth portion 50 is placed on and in contact with side two of the third portion 30 of the flexible foil 80. The conductive track or tracks 110 on side one of the flexible foil 80 are contacted to contact pads 210 on the bottom side and/or the top side of the electronic microsystem 200 and extend to the fifth portion 50 of the flexible foil 80 and enable a conductive connection with external contact pads on e.g. a printed circuit board without vias or throughholes in the isolating layer of the flexible foil 80. The conductive track or tracks 130 not shown in FIG. 4 can be used to interconnect contact pads 210 on the bottom side of the electronic microsystem 200 and contact pads 210 on the top side of the electronic microsystem 200. The electronic microsystem 200 may consist of two different devices placed on top of each other as e.g. a MEMS device and an IC.

A further embodiment of the invention is shown in FIG. 5 and FIG. 6. The flexible foil 80 has seven portions. FIG. 5 shows side two of the flexible foil 80 where conductive tracks 100 are placed on. The conductive tracks 100 extend from the fifth portion 50 to the seventh portion 70. As shown in FIG. 6 the electronic microsystem 200 is placed on side two of the first portion 10 of the flexible foil 80. In comparison to the embodiment shown in FIG. 2 the flexible foil is folded one time and side one of the first portion 10 is placed on and in contact with side one of the third portion 30 of the flexible foil 80. The fourth portion 40 covers at least parts of a side of the electronic microsystem 200 not placed on the first portion 10 of the flexible foil 80. The fifth portion 50 and seventh portion 70 are folded and placed on each other in a way that side one of the seventh portion 70 is placed on and in contact with side one of the fifth portion 50 and the conductive tracks 100 on side two of the flexible foil 80 can directly be contacted to the contact pads 210 of the electronic microsystem 200 and extend from the seventh portion 70 to the fifth portion 50 of the flexible foil 80 and enable a conductive connection with external contact pads on e.g. a printed circuit board without vias or throughholes in the isolating layer of the flexible foil 80.

A further embodiment is illustrated in FIG. 7a and FIG. 7b together with FIG. 8. FIG. 7a shows side one of the flexible foil 80 with seven portions and FIG. 7b shows side two of the flexible foil 80. There are conductive tracks 110 on side one of the flexible foil 80. The conductive track or tracks may result from patterning a conductive layer e.g. copper deposited on side one of the flexible foil 80 and extend from the first portion 10 to the third portion 30 of the flexible foil 80. The conductive track or tracks 100 placed on side two of the flexible foil 80 extend from the fourth portion 40 to the seventh portion 70 of the flexible foil 80. FIG. 6 shows the electrical microsystem 200 placed on side one of the first portion 10 of the flexible foil 80 in a way that at least one of the contact pads 210 of the electronic microsystem 200 is connected in a conductive way with at least one of the conductive tracks 110. The flexible foil 80 is folded in a way that the second portion 20 covers at least parts of a side of the electronic microsystem 200 not placed on the first portion 10 of the flexible foil 80. Further the flexible foil 80 is folded in a way that the seventh portion 70 is sandwiched between the third portion 30 and the fifth portion 50 of the flexible foil 80 and parts of side two of the fifth portion 50 of the flexible foil 80 are in contact with a side of the electronic microsystem 200 essentially parallel to the side of the electronic microsystem 200 placed on side one of the first portion 10 of the flexible foil 80. The conductive tracks 100 on side two of the seventh portion 70 of the flexible foil 80 and the conductive tracks 110 on side one of the third portion 30 of the flexible foil 80 have an overlapping area and can be connected in a conductive way by soldering or gluing with a conductive adhesive. The conductive track or tracks 100 contacted in the described way to the conductive track or tracks 110 extend from side two of the seventh portion 70 to side two of the fourth portion 40 of the flexible foil 80 in order to enable a conductive contact to external contact pacts placed e.g. on a printed circuit board without any via or throughholes in the flexible foil. Further the package method described in this embodiment can be used to contact further contact pads 210 on the bottom side of the electronic microsystem 200 as shown in FIG. 6 with contact pads on the top of the electronic microsystem 200 not shown in FIG. 6. This might be an advantage if the electronic microsystem 200 consist of a combination of e.g. a MEMS device and e.g. an IC placed on top of each other or every other combination of electronic devices placed on top of each other where a conductive interconnection is needed.

A further embodiment of the invention is shown in FIG. 9 and in FIG. 10. Both Figures show a side view of the flexible foil and the electronic system similar to FIG. 2. The flexible foil consists of an isolating layer and a conductive layer, the conductive layer e.g. realized by a thin copper layer is patterned by e.g. etching procedures in a way that at least one conductive track extends across all five portions 10, 20, 30, 40 and 50 of the flexible foil 80. On the first portion 10 of the flexible foil, further foils made of the same material as the flexible foil extending across all five portions are stacked on each other. These stacked foils might have a conductive layer on one or even both sides of the isolating layer. The foils itself and the conductive layers are patterned and stacked in a way that a MEMS device 220 is built as described in more detail in the European patent application 05108280.8 filed on Sep. 9, 2005 with the title “A method of manufacturing a microsystem, such a microsystem, a stack of foils comprising such a microsystem, an electronic device comprising such a microsystem and use of the electronic device”. Additionally there is a recess 240 in this embodiment where an IC 230 is placed in. The recess 240 built by the stack of patterned foils and the IC 230 are optional. There are spacers 300 on the third portion 30 and the fifth portion 50 which are built by stacks of foils. Between the spacers 300 and the stack of foils building the electronic system 200 there are gaps 310 and 320 where only the flexible foil is present enabling the folding of the flexible foil 80. The height of the spacers 300 and the height of the stack of foil building electronic system 200 comprising the MEMS device 220, the recess 240 and the IC 230 essentially determine the length of the second portion 20 and the fourth portion 40 of the flexible foil as can be seen in more detail in FIG. 10. FIG. 10 further shows that the flexible foil 80 is folded in the same way as already discussed in connection with FIG. 2. The Spacers 300 are placed on top of each other in way that the conductive track or tracks 100 can directly be contacted to the contact pads 210 of the MEMS device or the IC e.g. by soldering and side one of the fifth portion 50 of the flexible foil is inside the packaged device and side one of the fourth portion 40 and the third portion 30 of the flexible foil are at the outer surface of the packaged device thus the conductive track or tracks 100 extending from portion 50 to in this case portion 10 of the flexible foil can be connected to contact pads on a e.g. printed circuit board. The extension of the conductive track or tracks 100 up to the first portion 10 of the flexible foil is only exemplary and any extension from the fifth portion 50 to portion 40, 30, 20 or 10 is possible as long as a reliable contact from the packed device to external circuitry can be realized. Further there can be one or more conductive tracks (not shown in FIG. 9 and FIG. 10) comparable to conductive track 120 shown in FIG. 1b that can directly contact one or more contact pads of the MEMS device with one or more contact pads of the IC. The separate portion 10 with the electronic microsystem and the portions 30 and 50 with the spacers 300 are bonded on each other after the folding procedure illustrated in FIG. 10 by means of pressure and heat. In dependence of the selection of the foil material and the metallization the packaging procedure may result in a sealed or even hermetic package. Hermetic packaging has to be done by applying vacuum or protective gas during the folding and bonding procedure.

From the examples in the present disclosure it can be concluded that the invention can be used for manufacturing a packaged microsystem such as MEMS devices and microfluidic devices in an inexpensive manner. The enumeration of embodiments is by no means exhaustive. The products obtained by applying the method according the present invention can be used both in consumer electronics and in medical applications in which cooperation between electronic systems and the environment is necessary. The cost of these products is even so low that they may be used as disposable products. A number of concrete applications of the invention are listed below:

MEMS microphones for mobile telephones and PDAs;

Micropumps and fluid treatment in chemical analysis systems; and

Pressure sensors in tires.

As regards the selection of the foil material, many materials may be used, for example polyvinyl chloride (PVC), polyimide (PI), Poly(ethylene terephthalate) (PET), poly(ethylene 2,6-naphthalate) (PEN), polystyrene (PS), polymethyl methacrylate (PMMA), polypropylene, polyethene, polyurethane (PU), cellophane, polyester, parilene. In fact it amounts to this that any material that meets a number of criteria may be used. Attention should be paid that:

the thickness of the foil determines the vertical resolution;

the foil, as the basic material, must be manageable, preferably supplied on a roll;

the foil is capable of being metallized;

the metallized foil is capable of being preprocessed, preferably by means of a laser;

the foil can be bonded after stacking, preferably by using heat and pressure;

the material can be melted at “low” temperatures (<300 degrees); and

the foil stack, after stacking and bonding, possesses the properties that are required for the microsystem.

An important note in this connection is that the bonding of the foils preferably takes place at a temperature just below the melting point of the foil material. For example, if polyethylene terephthalate (PET) is used as the foil material (having a melting point of 255° C.), a temperature of, for example, 220° C. will be used.

More in particular, the foil material must be selected on the basis of the properties required for the application in question, viz.: temperature stability, shape stability, pressure resistance, optical and chemical properties.

Finally, inorganic, insulating foils may be used, such as mica.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, first, second and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

1. Method of manufacturing a microelectronic package comprising an electronic microsystem with electronic contact pads and at least one flexible foil consisting of an isolating layer and at least one conductive layer on at least one side of the isolating layer, comprising the following steps:
sectoring the flexible foil in at least five portions
structuring the at least one conductive layer in a way that there is at least one conductive track
placing the electronic microsystem on one portion of the flexible foil
folding the flexible foil in a way that the flexible foil covers at least parts of at least three sides of the electronic microsystem and at least two portions of the flexible foil are facing each other
contacting at least one contact pad of the electronic microsystem with at least one of the at least one conductive track of the conductive layer of the flexible foil in an electrically conductive way, wherein at least one conductive track contacted with the at least one contact pad extends to a surface of the microelectronic package so that the at least one conductive track extending to a surface of the microelectronic package can be contacted to other conductive structures not comprised by the electronic microsystem and the flexible foil.

2. Method according to claim 1 comprising the steps of:
sectoring the flexible foil in five subsequent portions, a first portion, a second portion, a third portion, a fourth portion and a fifth portion
structuring the at least one conductive track on the second side of the flexible foil in a way that the at least one conductive track extends from the fifth portion of the flexible foil at least to the fourth portion of the flexible foil and
placing the electronic microsystem on the first side of the first portion of the flexible foil.

3. Method according to claim 1 comprising the steps of:
sectoring the flexible foil in five subsequent portions, a first portion, a second portion, a third portion, a fourth portion and a fifth portion
structuring the at least one conductive track on the first side of the flexible foil in a way that the at least one conductive track extends at the latest from the third portion of the flexible foil at least to the fourth portion of the flexible foil and
placing the electronic microsystem on the first side of the first portion of the flexible foil.

4. Method according to claim 1, wherein the flexible foil has at least seven portions with two conductive layers one on each side of the isolating layer of the flexible foil, comprising the additional steps:
structuring the second conductive layer of the flexible foil in a way that after placing the electronic microsystem and folding the flexible foil there is at least one overlapping contact area between at least two conductive tracks with a first conductive track on the first and a second conductive track on the second side of the isolating layer of the flexible foil.
contacting the at least two conductive tracks in a electrically conductive way by means of the at least one overlapping contact area.

5. Method according to claim 1, wherein the electronic microsystem comprises at least one out of the group Micro ElectroMechanical System (MEMS), Microfluidic device and integrated circuit (IC).

6. Method according to claim 1, comprising the additional step of
manufacturing the electronic microsystem by stacking flexible foils used for the microelectronic package, whereby the electronic microsystem comprises at least a MEMS device or Microfluidic device.

7. Method according to claim 6, comprising the additional steps of
building a recess in the stack of foils building the electronic microsystem and
placing at least one IC the recess formed in the electronic microsystem.

8. Method according to claim 1, comprising the additional step of exerting pressure at an elevated temperature to join the electronic microsystem with the flexible foil and establish an electrically conducting contact between the conductive tracks an the contact pads.

9. Method according to claim 8, comprising the additional step of structuring the at least one conductive layer of the flexible foil in a way that on at least one surface of the microsystem being in contact with the flexible foil (80) at least one area is built that can be joined with the flexible foil in a gas-tight way and the at least one area is arranged as a sealing ring around all other areas on the at least one surface of the microsystem in contact with the flexible foil where the flexible foil with at least one structured conductive layer and the microsystem are joined in a non gas-tight way.

10. Method according to claim 1, whereby the material for the conductive layer is selected from the group consisting of aluminum, platinum, silver, gold, copper and indium tin oxide.

11. Method according to claim 1, whereby the isolating layer of the flexible foil is selected from the group consisting of polyphenyl sulphide (PPS) and polyethylene terephthalate (PET).

12. Method according to claim 1, whereby the flexible foil has a thickness between 1 □m and 100 □m.

13. Method according claim 5, whereby the flexible foil has a thickness between 1 □m and 5 □m.

14. Microelectronic package comprising an electronic microsystem with electronic contact pads and at least one flexible foil consisting of an isolating layer and at least one conductive layer on at least one side of the isolating layer, wherein
the flexible foil has at least five portions
the conductive layer comprises at least one conductive track
the folded flexible foil covers at least parts of at least three sides of the electronic microsystem and at least two portions of the flexible foil are facing each other.
at least one contact pad of the electronic microsystem is contacted with at least one of the at least one conductive track of the conductive layer of the flexible foil in an electrically conductive way, wherein the at least one conductive track contacted with the at least one contact pad extends to a surface of the microelectronic package so that the at least one conductive track extending to a surface of the microelectronic package can be contacted to other conductive structures not comprised by the electronic microsystem and the flexible foil.
